(19) United States
(12) Patent Application Publication
(10) Pub. No.: US 2025/0160084 A1
(43) Pub. Date: May 15, 2025

(54) MICRO LED AND MICRO LED DISPLAY PANEL

(71) Applicant: JADE BIRD DISPLAY (SHANGHAI) LIMITED, SHANGHAI (CN)

(72) Inventors: Qunchao XU, Shanghai (CN); Weisin TAN, Shanghai (CN)

(21) Appl. No.: 18/940,896

(22) Filed: Nov. 8, 2024

(30) Foreign Application Priority Data
Nov. 9, 2023 (WO) PCT/CN2023/130740

(51) Int. Cl. H01L 33/62; H01L 25/075

(52) U.S. Cl. CPC H10H 20/857; H01L 25/0753

(57) ABSTRACT

A micro LED includes a bonding layer provided at a bottom of the micro LED; and two or more light emitting mesas provided on the bonding layer and disposed in a vertical direction from top to bottom, wherein the two or more light emitting mesas are electrically connected in parallel.

### CROSS-REFERENCE TO RELATED APPLICATIONS

The present disclosure claims the benefits of priority to PCT Application No. PCT/CN2023/130740, filed on Nov. 9, 2023, which is incorporated herein by reference in its entirety.

### TECHNICAL FIELD

The present disclosure generally relates to micro LED manufacturing technology, and more particularly, to a micro LED and a micro LED display panel.

### BACKGROUND

Inorganic micro pixel light emitting diodes, also referred to as micro light emitting diodes (LEDs), micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED can include a light emitting mesa and electrical connection to electrodes, so that the micro LED can be controlled. Since a pitch and a dimension of the micro LED become smaller and smaller, light emission efficiency may seriously degrade.

### SUMMARY OF THE DISCLOSURE

Embodiments of the present disclosure provide a micro LED. The micro LED includes a bonding layer provided at a bottom of the micro LED; and two or more light emitting mesas provided on the bonding layer and disposed in a vertical direction from top to bottom, wherein the two or more light emitting mesas are electrically connected in parallel.

Embodiments of the present disclosure also provide a micro LED display panel. The micro LED display panel includes an integrated circuit (IC) backplane including a bottom pad array, the bottom pad array comprising a plurality of bottom pads; and a micro LED array formed on the IC backplane, the micro LED array comprising a plurality of micro LEDs. One micro LED of the plurality of micro LEDs is electrically connected to one bottom pad of the plurality of bottom pads, and each of the plurality of micro LEDs includes a bonding layer bonded to the IC backplane, and two or more light emitting mesas formed on the bonding layer; wherein the two or more light emitting mesas are disposed in a vertical direction from top to bottom and electrically connected in parallel.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a sectional view of an exemplary micro LED display panel, according to some embodiments of the present disclosure.

FIG. 2 is a circuit diagram schematically illustrating two light emitting mesas electrically connected in parallel, according to some embodiments of the present disclosure.

FIG. 3A illustrates a structural diagram showing a top view of micro LED display panel shown in FIG. 1, according to some embodiments of the present disclosure.

FIG. 3B illustrates a structural diagram showing another top view of micro LED display panel shown in FIG. 1, according to some embodiments of the present disclosure.

FIG. 4A illustrates a structural diagram showing a top view of micro LED display panel shown in FIG. 1 with top conductive layer and enhance pad removed, according to some embodiments of the present disclosure.

FIG. 4B illustrates a structural diagram showing another top view of micro LED display panel shown in FIG. 1 with top conductive layer and enhance pad removed, according to some embodiments of the present disclosure.

FIG. 5 illustrates a structural diagram showing a sectional view of another exemplary micro LED display panel, according to some embodiments of the present disclosure.

FIG. 6 illustrates a structural diagram showing a sectional view of another exemplary micro LED display panel, according to some embodiments of the present disclosure.

FIG. 7 illustrates a structural diagram showing a top view of a micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Embodiments of the present disclosure provide a micro LED having improved light emission efficiency. The micro LED includes multiple light emitting mesas in parallel.

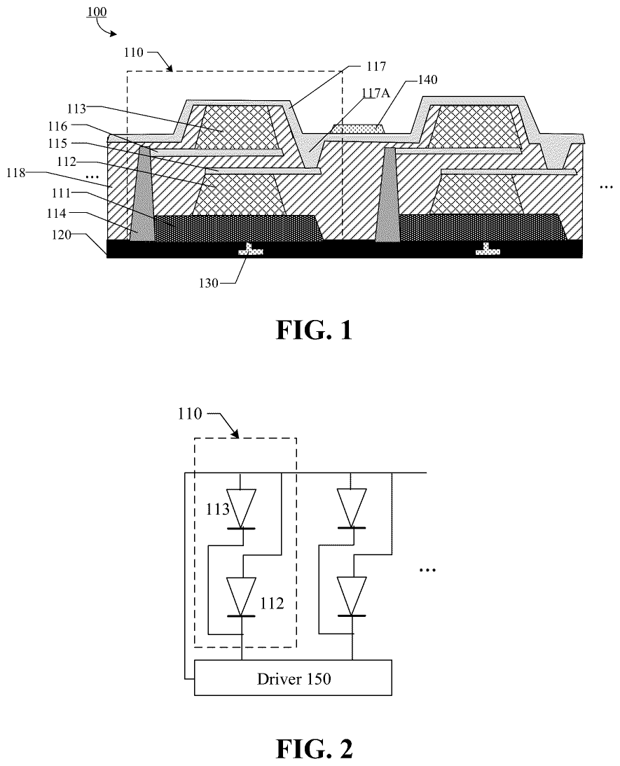

FIG. 1 illustrates a structural diagram showing a sectional view of an exemplary micro LED display panel 100, according to some embodiments of the present disclosure. A micro LED consistent with the present disclosure includes two or more light emitting mesas electrically connected in parallel. In FIG. 1, two adjacent micro LEDs are illustrated. Micro LED display panel 100 includes a micro LED array including a plurality of micro LEDs 100 and an IC (integrated Circuit) backplane 120. The plurality of micro LEDs 110 are provided on IC backplane 120.

As shown in FIG. 1, micro LED 110 includes a bonding layer 111. Bonding layer 111 is bonded with IC backplane 120. In some embodiments, bonding layer 111 is bonded with IC backplane 120 by a bottom pad 130. In some embodiments, a material of bonding layer 111 is metal. For example, the material may include: Al, Au, Rh, Ag, Cr, Ti, Pt, Sn, Cu, etc. The material may also include one or more metal alloys, for example, AuSn, TiW, and the like. A first light emitting mesa 112 and a second light emitting mesa 113 are provided on bonding layer 111 and disposed in a vertical direction from bottom to top. First light emitting mesa 112 is formed on bonding layer 111 and electrically connected to bonding layer 111. Second light emitting mesa 113 is provided above first light emitting mesa 112. First light emitting mesa 112 and a second light emitting mesa 113 are electrically connected in parallel. For example, a bottom of first light emitting mesa 112 and a bottom of second light emitting mesa are connected to a first electrode (e.g., P-pad, not shown), and a top of first light emitting mesa 112 and a top of second light emitting mesa 113 are connected to a second electrode (e.g., N-pad, not shown). FIG. 2 is a circuit diagram schematically illustrating the two light emitting mesas electrically connected in parallel, according to some embodiments of the present disclosure. As shown in FIG. 2, a light emitting mesa (e.g., light emitting mesa 112 or 113) can be considered as a diode, and first light emitting mesa 112 and second light emitting mesa 113 are electrically connected in parallel. Referring to FIG. 1 and FIG. 2, a driver 150 can be connected to micro LED 110 and configured to control each micro LED 110. In some embodiments, driver 150 can be integrated into IC backplane 120.

Referring to FIG. 1, a bottom connection structure 114 is provided at a side of first light emitting mesa 112 and second light emitting mesa 113. Bottom connection structure 114 is used to electrically connect the bottom of first light emitting mesa 112 and the bottom of second light emitting mesa 113. In some embodiments, second light emitting mesa 113 further includes a bottom connection layer 116 formed at a bottom of second light emitting mesa 113 and electrically connected to bottom connection structure 114 and the bottom of second light emitting mesa 113. Therefore, the bottom of second light emitting mesa 113 is electrically connected to bottom connection structure 114 by bottom connection layer 116. Bottom connection structure 114 is further electrically connected to bonding layer 111. For example, bottom connection structure 114 is electrically connected to a sidewall of bonding layer 111. Therefore, bottom connection structure 114 can electrically connect the bottom of first light emitting mesa 112 and the bottom of second light emitting mesa 113 to the first electrode, for example, a P-pad. In some embodiments, a bottom of bottom connection structure 114 is aligned with a bottom of bonding layer 111. In some embodiments, a top of bottom connection structure is aligned with a bottom of second light emitting mesa 113. In some embodiments, bottom connection structure 114 is non-transparent. A material of bottom connection structure 114 is metal. Therefore, bottom connection structure 114 can also isolate light interference from adjacent micro LEDs. In some embodiments, bottom connection structure 114 surrounds half of a circumference of micro LED 110.

Micro LED 110 further includes a top conductive layer 117 formed on a top of micro LED 110 and electrically connected to the top of second light emitting mesa 113 and the top of first light emitting mesa 112. For example, as shown in FIG. 1, first light emitting mesa 112 includes a top connection layer 115 formed on the top of first light emitting mesa 112 and extending outwards from first light emitting mesa 112. Top conductive layer 117 includes a sunk portion 117A extending downwards to first light emitting mesa 112 and electrically connected to top connection layer 115 of first light emitting mesa 112. Therefore, top conductive layer 117 can electrically connect the top of first light emitting mesa 112 and the top of second light emitting mesa 113. Furthermore, top conductive layer 117 can further connect to the second electrode, e.g., a N-pad. With this structure, bottoms of first light emitting mesa 112 and second light emitting mesa 113 are connected to the first electrode, and tops of first light emitting mesa 112 and second light emitting mesa 113 are connected to the second electrode. Therefore, first light emitting mesa 112 and second light emitting mesa 113 are connected in parallel.

In some embodiments, top conductive layer 117, top connection layer 115, and bottom connection layer 116 are transparent. In some embodiments, top conductive layer 117, top connection layer 115, and bottom connection layer 116 are TCO (transparent conductive oxide) thin layers, for example, ITO (Indium Tin Oxide) layers, AZO (Antimony doped Zinc Oxide) layers, ATO (Antimony doped Tin Oxide) layers, FTO (Fluorine doped Tin Oxide) layers, and the like.

In some embodiments, a light emitting area of first light emitting mesa 112 and a light emitting area of second light emitting mesa 113 can be the same. First light emitting mesa 112 and second light emitting mesa 113 have the same size.

In some embodiments, micro LED 110 further includes a dielectric material 118 filled between and around first light emitting mesa 112 and second light emitting mesa 113. Dielectric material 118 is transparent. A material of dielectric material 118 can be selected from one or more of SiO₂, SiON, Al₂O₃, or SiN, etc.

In some embodiment, top conductive layer 117 is interconnected and continuously formed on top surfaces of the plurality of micro LEDs 110. Top conductive layer 117 electrically connects to the top of second light emitting mesa 113 and the top of first light emitting mesa 112 and connects to the second electrode (e.g., N-pad). Since bonding layer 111 of micro LED 110 is connected to IC backplane 120 with respective bottom pad 130. Each micro LED 110 of the plurality of micro LEDs can be controlled independently, for example, by driver 150 (as shown in FIG. 2).

In some embodiments, micro LED display panel 100 further includes an enhance pad 140 provided on top conductive layer 117 to increase the conductivity of top conductive layer 117. In some embodiments, enhance pad 140 is provided between adjacent micro LEDs. In some embodiments, enhance pad 140 has a mesh structure.

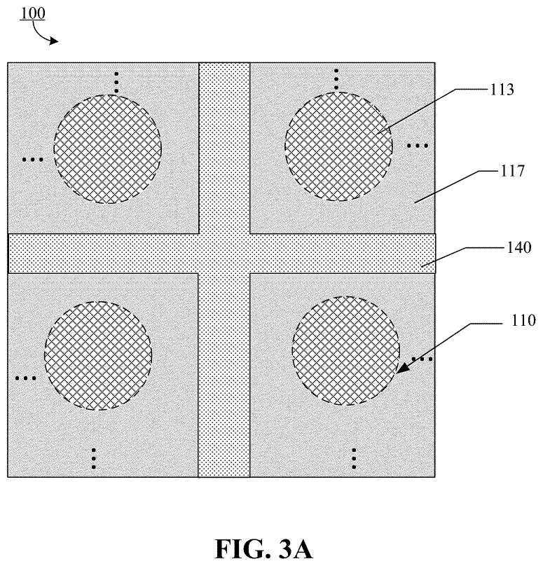

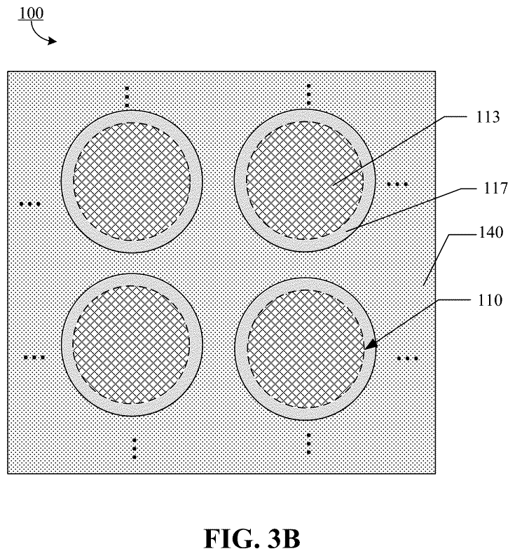

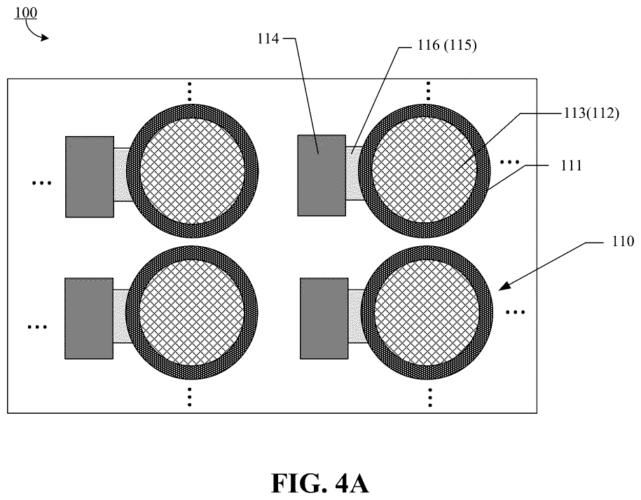

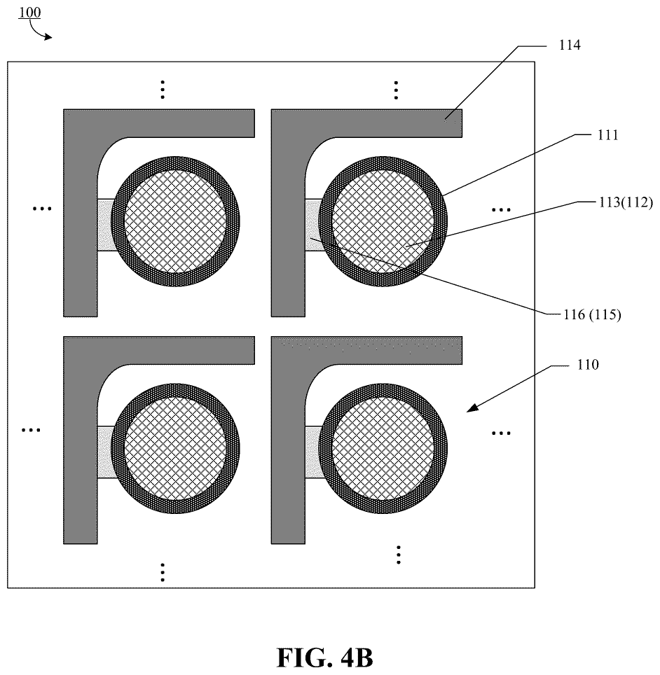

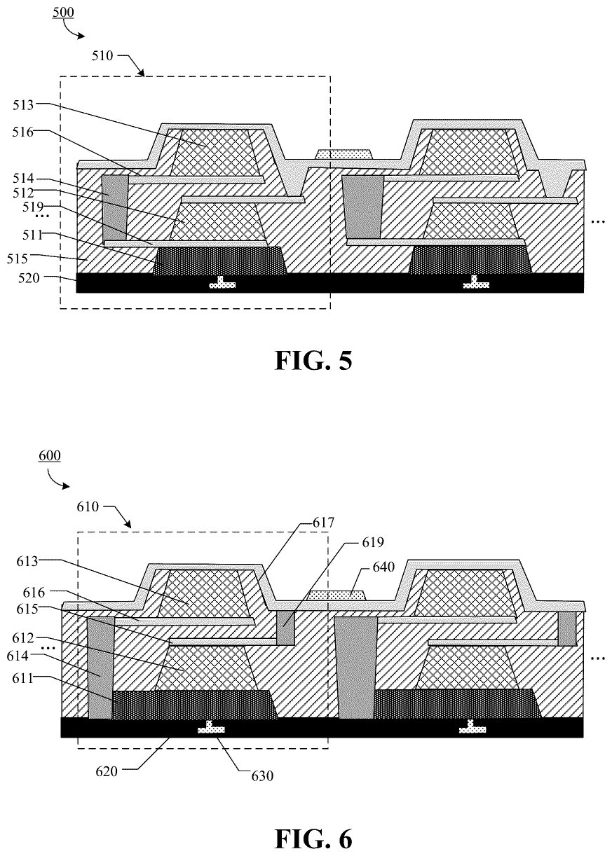

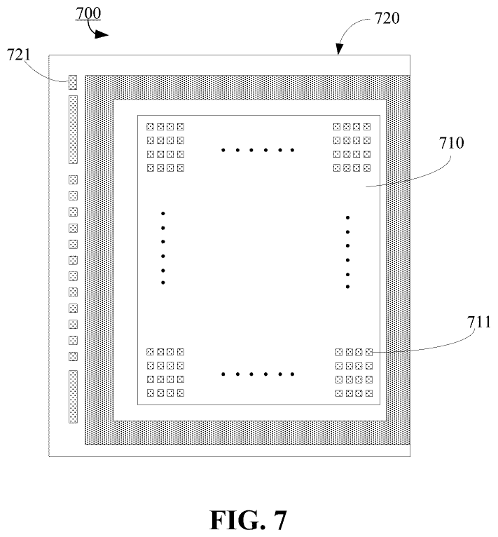

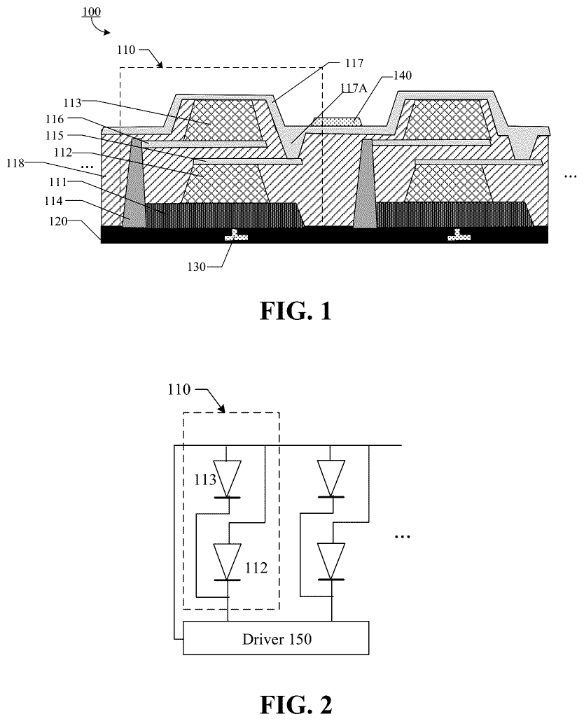

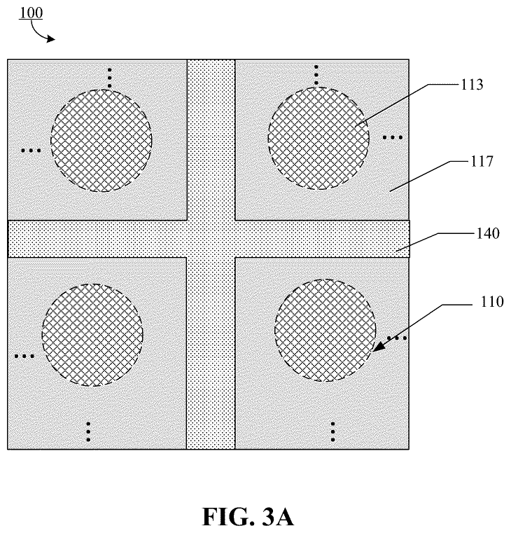

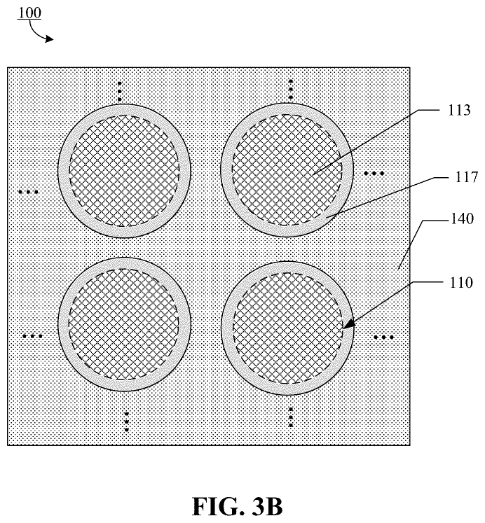

FIG. 3A illustrates a structural diagram showing a top view of micro LED display panel 100 shown in FIG. 1, according to some embodiments of the present disclosure. Consistent with FIG. 1, referring to FIG. 3A, top conductive layer 117 is continuously formed on micro LED display panel 100. In this example, enhance pad 140 is provided on top conductive layer 117 between adjacent micro LEDs 110 (including bonding layer 111, first light emitting mesa 112, and second light emitting mesa 113) and illustrated as a grid. A shape of exposed part of top conductive layer 340 is rectangular.

FIG. 3B illustrates a structural diagram showing another top view of micro LED display panel 100 shown in FIG. 1, according to some embodiments of the present disclosure. Consistent with FIG. 1, referring to FIG. 3B, top conductive layer 117 is continuously formed on micro LED 100. In this example, enhance pad 140 is provided on top conductive layer 117 between adjacent micro LEDs 110 (including boing layer 111, first light emitting mesa 112, and second light emitting mesa 113) and illustrated as a mesh. A shape of exposed part of top conductive layer 117 is round.

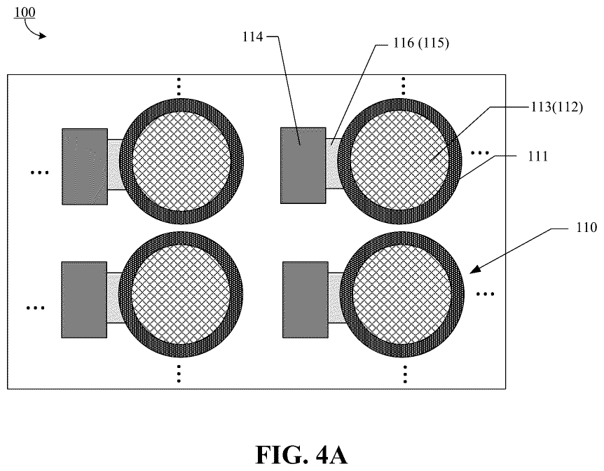

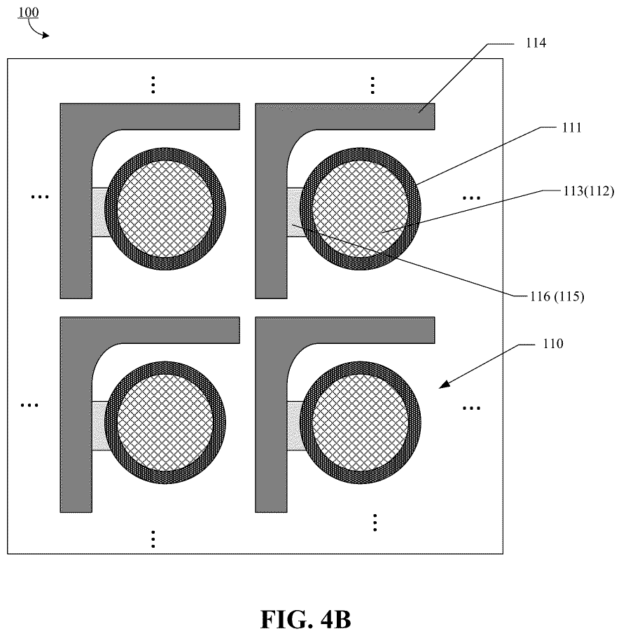

FIG. 4A illustrates a structural diagram showing a top view of micro LED display panel 100 shown in FIG. 1 with top conductive layer and enhance pad removed, according to some embodiments of the present disclosure. Consistent with FIG. 1, referring to FIG. 4A, bottom connection structure 114 is provided at a side of micro LED 110 (e.g., including bonding layer 111, first light emitting mesa 112, and second light emitting mesa 113). Bottom connection structure 114 is connected to first light emitting mesa 112 by top connection layer 115 and connected to second light emitting mesa 113 by bottom connection layer 116.

FIG. 4B illustrates a structural diagram showing another top view of micro LED display panel 100 shown in FIG. 1 with top conductive layer and enhance pad removed, according to some embodiments of the present disclosure. Consistent with FIG. 1, referring to FIG. 4B, bottom connection structure 114 is provided surrounding half of a circumference of micro LED 110 (e.g., including bonding layer 111, first light emitting mesa 112, and second light emitting mesa 113). Bottom connection structure 114 is connected to first light emitting mesa 112 by top connection layer 115 and connected to second light emitting mesa 113 by bottom connection layer 116. In this example, bottom connection structure 114 can also isolate light interference from adjacent micro LEDs 110.

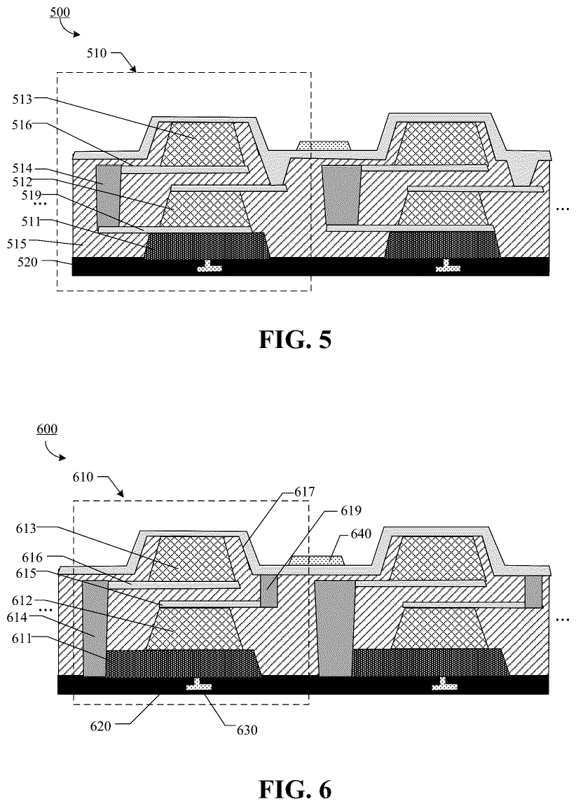

FIG. 5 illustrates a structural diagram showing a sectional view of another exemplary micro LED display panel 500, according to some embodiments of the present disclosure. Micro LED display panel 500 includes a micro LED array including a plurality of micro LEDs 510 provided on an IC backplane 520. As shown in FIG. 5, micro LED 510 includes a bonding layer 511, a first light emitting mesa 512, a second light emitting mesa 513, and a bottom connection structure 514. In this example, first light emitting mesa 512 further includes a first bottom connection layer 519 formed at a bottom of first light emitting mesa 512 and electrically connected to the bottom of first light emitting mesa 512. First bottom connection layer 519 is provided between the bottom of first light emitting mesa 512 and bonding layer 511 to electrically connect the bottom of first light emitting mesa 512 and bonding layer 511. First bottom connection layer 519 extends outwards from first light emitting mesa 512 to electrically connect to bottom connection structure 514. Second light emitting mesa 513 further includes a second bottom connection layer 516 formed at a bottom of second light emitting mesa 513 and electrically connected to the bottom of second light emitting mesa 513. Second bottom connection layer 516 extends outwards from second light emitting mesa 513 to electrically connect to bottom connection structure 514. Therefore, bottom connection structure 514 electrically connects the bottom of first light emitting mesa 512 and the bottom of second light emitting mesa 513. The bottom of first light emitting mesa 512 and the bottom of second light emitting mesa 513 can further connect to the first electrode (not shown) by bonding layer 511. In some embodiments, a material of bonding layer 511 is metal. For example, the material may include: Al, Au, Rh, Ag, Cr, Ti, Pt, Sn, Cu, etc. The material may also include one or more metal alloys, for example, AuSn, TiW, and the like.

In this example, bottom connection structure 514 does not connect to bonding layer 511 directly but instead indirectly connects via first bottom connection layer 519. A bottom of bottom connection structure 514 is aligned with a top of bonding layer 511.

In some embodiments, micro LED display panel500 further includes dielectric material 515 filled between and around first light emitting mesa 512 and second light emitting mesa 513. Dielectric material 515 is transparent. A material of dielectric material 515 can be selected from one or more of SiO₂, SiON, Al₂O₃, or SiN, etc.

Description of other features of micro LED display panel 500 may be found by referring to corresponding features described above with reference to FIG. 1, which will not be repeated here.

FIG. 6 illustrates a structural diagram showing a sectional view of another exemplary micro LED display panel 600, according to some embodiments of the present disclosure. Micro LED display panel 600 includes a micro LED array including a plurality of micro LED 610 provided on an IC backplane 620. As shown in FIG. 6, micro LED 610 includes a bonding layer 611, a first light emitting mesa 612, a second light emitting mesa 613, and a bottom connection structure 614. Bottom connection structure 614 is electrically connected to a bottom of second light emitting mesa 613. For example, bottom connection structure 614 is electrically connected to the bottom of second light emitting mesa 613 by a bottom connection layer 616. Bottom connection structure 614 is further electrically connected to bonding layer 611. Since the bottom of first light emitting mesa 612 is electrically connected to bonding layer 611, the bottom of first light emitting mesa 612 and the bottom of second light emitting mesa 613 are both electrically connected to bonding layer 611, and further connected to a first electrode (not shown), e.g., P-pad. In some embodiments, a bottom of bottom connection structure 614 is aligned with a bottom of bonding layer 611. A top of bottom connection structure 614 is aligned with a bottom of second light emitting mesa 613.

In this example, micro LED 610 further includes a top connection structure 619 electrically connected to a top of first light emitting mesa 612 and a top of second light emitting mesa 613. A top conductive layer 617 is provided on the top of second light emitting mesa 613 and electrically connected to the top of second light emitting mesa 613. First light emitting mesa 612 includes a top connection layer 615 formed on the top of first light emitting mesa 612 and electrically connected to the top of first light emitting mesa 612. Top connection structure 619 is provided at another side of first light emitting mesa 612 and second light emitting mesa 613 and under top conductive layer 617. Top connection structure 619 is electrically connected to top conductive layer 617 and top connection layer 615. Therefore, first light emitting mesa 612 and second light emitting mesa 613 are connected in parallel through top connection structure 619 and bottom connection structure 614.

In some embodiments, top connection layer 615 and bottom connection layer 616 are transparent. In some embodiments, top connection layer 615 and bottom connection layer 616 are TCO (transparent conductive oxide) thin layers, for example, ITO (Indium Tin Oxide) layers, AZO (Antimony doped Zinc Oxide) layers, ATO (Antimony doped Tin Oxide) layers, FTO (Fluorine doped Tin Oxide) layers, and the like.

In some embodiments, a light emitting area of first light emitting mesa 612 and a light emitting area of second light emitting mesa 613 are the same. First light emitting mesa 612 and second light emitting mesa 613 have the same size.

In some embodiments, a top surface area of bonding layer 611 is greater than a bottom surface area of first light emitting mesa 612.

In some embodiments, top conductive layer 617 of the plurality of micro LEDs is interconnected and continuously formed on top surfaces of the plurality of micro LEDs 610. Top conductive layer 617 electrically connects the top of first light emitting mesa 612 and the top of second light emitting mesa 613 to a second electrode (e.g., N-pad, not shown). Since bonding layer 611 of micro LED 610 is connected to IC backplane 620 with respective bottom pad 630, each micro LED 610 of the plurality of micro LEDs can be controlled independently.

In some embodiments, micro LED display panel 600 further includes an enhance pad 640 provided on top conductive layer 617 to increase the conductivity of continuously top conductive layer 617. In some embodiments, enhance pad 640 is provided between adjacent micro LEDs. In some embodiments, enhance pad 640 has a mesh structure.

Description of other features of micro LED display panel 600 may be found by referring to corresponding features described above with reference to FIG. 1, which will not be repeated here.

With reference to FIG. 1 to FIG. 6, it can be understood that two or more light emitting mesas can be provided in a vertical direction and electrically connected in parallel in a similar way.

In some embodiments, the two or more light emitting mesas emit the same color light, thereby increasing the light emission efficiency of for a single-color LED.

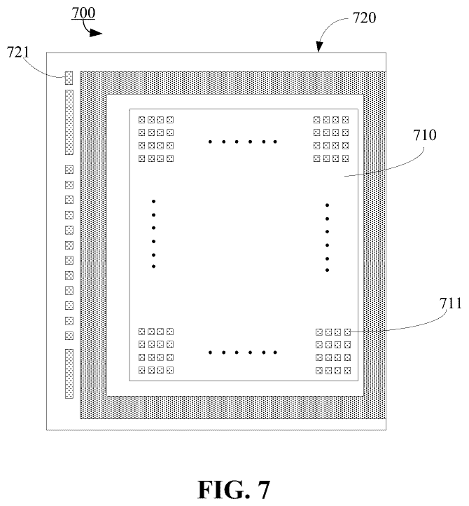

FIG. 7 illustrates a structural diagram showing a top view of a micro LED display panel 700, according to some embodiments of the present disclosure. Referring to FIG. 7, micro LED display panel 700 includes a micro LED array 710 and an IC backplane 720. Micro LED array 710 is located on IC backplane 720 to form an image display area of micro LED display panel 700. The rest of the area on IC backplane 720 not covered by micro LED array 710 is formed as a non-functional area. IC backplane 720 is formed at the back surface of micro LED array 710 with a part extending outside of, i.e., not covered by, micro LED array 710. Micro LED array 710 includes a plurality of micro LEDs 711 provided in an array. IC backplane 720 is configured to control the plurality of micro LEDs 711. IC backplane 720 may include a bottom pad array (not shown) corresponding to micro LED array 710. The bottom pad array includes a plurality of bottom pads (e.g., bottom pads 130 or 630), and one bottom pad corresponds to one micro LED 711. One micro LED of the plurality of micro LEDs is electrically connected with one bottom pad.

In some embodiments, a top conductive layer (for example, top conductive layer 117 in FIG. 1 or top conductive layer 617 in FIG. 6) of micro LED 711 is interconnected with each of the plurality of micro LED 711. That is, the top conductive layer is continuously formed on a top of micro LED array 710 and connected with every micro LED 711. In some embodiments, an enhance pad (e.g., enhance pad 140 in FIG. 1, enhance pad 540 in FIG. 5, or enhance pad 640 in FIG. 6) is provided on top conductive layer between the adjacent micro LEDs 711. The enhance pads are interconnected to improve the conductivity of the top connective layer.

In some embodiments, IC backplane 720 further includes a top connected pad 721. The top conductive layer (e.g., top conductive layer 117 in FIG. 1 and top conductive layer 617 in FIG. 6) is connected with top connected pad 721.

Each micro LED herein (e.g., micro LED 110, 510, 610) has a very small volume. The micro LED can be applied in a micro LED display panel. The light emitting area of the micro LED display panel, e.g., micro LED display panel 700, is very small, such as 1 mm×1 mm, 3 mm×5 mm, etc. In some embodiments, the light emitting area is the area of the micro LED array in the micro LED display panel. The micro LED display panel includes one or more micro LEDs that form a pixel array in which the micro LEDs are pixels, such as a 1600×1200, 680×480, or 1920×1080-pixel array. The diameter of each micro LED is in the range of about 200 nm to 2 μm. An IC backplane, e.g., IC backplane 720, is formed at the back surface of micro LED array 710 and is electrically connected with micro LED array 710. IC backplane 720 acquires signals such as image data from outside via signal lines to control corresponding micro LEDs 711 to emit light or not.

It is understood by those skilled in the art that the micro LED display panel is not limited by the structure described above and may include greater or fewer components than those illustrated, or some components may be combined, or a different component may be utilized.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED (light emitting diode), comprising:
a bonding layer provided at a bottom of the micro LED; and
two or more light emitting mesas provided on the bonding layer and disposed in a vertical direction from top to bottom, wherein the two or more light emitting mesas are electrically connected in parallel.

2. The micro LED according to claim 1, wherein the two or more light emitting mesas comprises:
a first light emitting mesa provided on the bonding layer and electrically connected to the bonding layer; and
a second light emitting provided above the first light emitting mesa, a bottom of the first light emitting mesa and a bottom of the second light emitting mesa being electrically connected, and a top of the first light emitting mesa and a top of the second light emitting mesa being electrically connected.

3. The micro LED according to claim 2, further comprising a bottom connection structure provided at a side of the two or more light emitting mesas and configured to connect the bottom of the first light emitting mesa and the bottom of the second light emitting mesa.

4. The micro LED according to claim 3, wherein the second light emitting mesa comprises a bottom connection layer formed at bottom of the second light emitting mesa and extending outwards from the second light emitting mesa to electrically connect to the bottom connection structure; and the bottom connection structure is electrically connected to the bonding layer.

5. The micro LED according to claim 3, wherein the first light emitting mesa comprises a first bottom connection layer formed between a bottom of the first light emitting mesa and the bonding layer to electrically connect the bottom of the first light emitting mesa and the bonding layer, the first bottom connection layer extending outwards from the first light emitting mesa to electrically connect to the bottom connection structure, the second light emitting mesa comprises a second bottom connection layer formed at bottom of the second light emitting mesa and extending outwards from the second light emitting mesa to electrically connect to the bottom connection structure.

6. The micro LED according to claim 3, wherein a bottom of the bottom connection structure is aligned with a bottom of the bonding layer.

7. The micro LED according to claim 6, wherein a top of the bottom connection structure is aligned with a bottom of the second light emitting mesa.

8. The micro LED according to claim 7, wherein the bottom connection structure is further configured for light isolation.

9. The micro LED according to claim 8, wherein the bottom connection structure surrounds half of a circumference of the micro LED.

10. The micro LED according to claim 2, further comprising a top conductive layer formed on a top of the micro LED and electrically connected to the top of the second light emitting mesa and the top of the first light emitting mesa.

11. The micro LED according to claim 10, wherein the first light emitting mesa comprises a top connection layer formed on the top of the first light emitting mesa and extending outwards from the first light emitting mesa; and the top conductive layer comprises a sunk portion electrically connected to the top connection layer of the first light emitting mesa.

12. The micro LED according to claim 10, wherein the first light emitting mesa comprises a top connection layer formed on the top of the first light emitting mesa and extending outwards from the first light emitting mesa; and the micro LED further comprises a top connection structure electrically connected the top connection layer of the first light emitting mesa and the top conductive layer.

13. A micro LED (light emitting diode) display panel comprises:
an integrated circuit (IC) backplane comprising a bottom pad array, the bottom pad array comprising a plurality of bottom pads; and
a micro LED array formed on the IC backplane, the micro LED array comprising a plurality of micro LEDs;
wherein one micro LED of the plurality of micro LEDs is electrically connected to one bottom pad of the plurality of bottom pad, and each of the plurality of micro LEDs comprises:
a bonding layer bonded with the IC backplane; and
two or more light emitting mesas provided on the bonding layer and disposed in a vertical direction from top to bottom, wherein the two or more light emitting mesas are electrically connected in parallel.

14. The micro LED display panel according to claim 13, wherein the two or more light emitting mesas comprises:
a first light emitting mesa provided on the bonding layer and electrically connected to the bonding layer; and
a second light emitting mesa provided above the first light emitting mesa, a bottom of the first light emitting mesa and a bottom of the second light emitting mesa being electrically connected, and a top of the first light emitting mesa and a top of the second light emitting mesa being electrically connected.

15. The micro LED display panel according to claim 14, wherein the micro LED further comprises a top conductive layer formed on a top of each of the plurality of the micro LED and electrically connected to the top of the second light emitting mesa and the top of the first light emitting mesa.

16. The micro LED display panel according to claim 15, wherein the top conductive layers of the plurality of micro LEDs are interconnected.

17. The micro LED display panel according to claim 16, further comprising an enhance pad provided on the top conductive layer and between adjacent micro LEDs, the enhance pad configured to increase conductivity of the top conductive layer.

18. The micro LED display panel according to claim 16, wherein the IC backplane further comprises a top connected pad, and the top conductive layer is connected to the top connected pad of the IC backplane.

19. The micro LED display panel according to claim 14, wherein the micro LED further comprises a bottom connection structure provided at a side of the two or more light emitting mesas and configured to connect the bottom of the first light emitting mesa and the bottom of the second light emitting mesa.
